(19) United States
(12) Patent Application Publication
(10) Pub. No.: US 2006/0049401 A1
(43) Pub. Date: Mar. 9, 2006

(54) Nitride epitaxial layer structure and method of manufacturing the same

(76) Inventors: Tzu-Chi Wen, Tainan City (TW); Ru-Chin Tu, Tainan City (TW); Cheng-Tsang Yu, Wufong Township (TW); Liang-Wen Wu, Banciao City (TW); Fen-Ren Chien, Yonghe City (TW)

Correspondence Address: SUPREME PATENT SERVICES, P.O. BOX 2339, SARATOGA, CA, 95070-0339, US

(21) Appl. No.: 10/937,466

(22) Filed: Sep. 8, 2004

(51) Int. Cl. H01L 29/04

(52) U.S. Cl. 257/49

(57) ABSTRACT

Disclosed is a nitride epitaxial layer structure and manufacturing method thereof. The structure includes a substrate, which is used as the basic supporting material, a first immediate layer formed by stacking an appropriate thickness of high temperature aluminum-gallium-indium-nitride (Al_{1-x-y}GaₓIn_{y}N) on the substrate, a second immediate layer formed by re-crystallizing an appropriate thickness of low temperature aluminum-gallium-indium-nitride (Al_{1-x-y}GaₓIn_{y}N) stacked on the first immediate layer, and a nitride epitaxial layer formed by stacking nitride epitaxial material on the second immediate layer. The structure so formed can improve and alleviate the problem of excessively high defect density of the low temperature aluminum-gallium-indium-nitride (Al_{1-x-y}GaₓIn_{y}N), and thus be able to enhance the characteristics of its elements.

### BACKGROUND OF THE INVENTION

1. Field of the Invention

The present invention relates to a nitride epitaxial layer structure and a method of manufacturing the same, and in particular relates to a nitride epitaxial layer structure containing the special intermediate layer and its manufacturing process.

2. The Prior Arts

In the traditional gallium-nitride (GaN) based light-emitting diode buffer layer structure, a buffer layer is formed on a substrate, and then a gallium-nitride (GaN) based nitride epitaxial layer is formed on that buffer layer. This kind of buffer layer is obtained by depositing the GaN or AlₓGa₁₋ₓN or InₓGa₁₋ₓN at low temperature (200-900° C.), and the gallium-nitride (GaN) is grown at high temperature to form its nitride epitaxial layer. However, due to the excessively large difference between the lattice constant of gallium nitride and that of the substrate, the defect density of the gallium nitride grown from this kind of buffer layer at low temperature could reach as high as 10¹⁰/cm³ or above. The buffer layer structure of light emitting diode made of such gallium nitride material tends to make the ESD endurance voltage of the element drop to too low, and resulting in the shortening of its service life, and the deterioration of the features of its elements.

Therefore, the purpose of the present invention is to overcome the above-mentioned shortcomings, and the development and creation of the present invention is based on the efforts in correcting the defects of the conventional nitride epitaxial buffer layer structure.

### SUMMARY OF THE INVENTION

The present invention relates to a nitride epitaxial layer structure and a method of manufacturing the same, it practically solves one of several above-mentioned restrictions and shortcomings of the related prior art.

Therefore, the present invention provides a nitride epitaxial layer structure and its manufacturing method, its main purpose is to provide an appropriate immediate layer structure and its manufacturing process, to improve the lattice constants difference between the nitride epitaxial layer and the substrate, so as to reduce the defect density of nitride epitaxial layer which originally could reach as high as 10¹⁰/cm³.

To achieve the above-mentioned purpose, the present invention provides a nitride epitaxial layer structure and its manufacturing method, and it is mainly characterized in that: to grow a first immediate layer of high temperature aluminum-gallium-indium-nitride (Al_{1-x-y}GaₓIn_{y}N) and a second immediate layer of low temperature aluminum-gallium-indium-nitride (Al_{1-x-y}GaₓIn_{y}N) both of appropriate thickness on a substrate through epitaxy; and then perform the recrystallization of the second immediate layer, so as to make its crystal lattices to form in orderly alignment, and to serve as the immediate layer in depositing the nitride epitaxial layer. As such, the formation of the second immediate layer of the loosely constructed and amorphous lattice alignment, enables the filling in the uneven surface portions of the first immediate layer, and then through carrying out the re-crystallization of the second immediate layer, so as to make the lattices to form in orderly alignment. Therefore, the present invention can improve and alleviate the problem of excessively high defect density of the low temperature aluminum-gallium-indium-nitride (Al_{1-x-y}GaₓIn_{y}N), and thus enhancing the characteristics of its elements.

The purpose and functions of the present invention can be understood more thoroughly through the following detailed description together with the attached drawings.

### BRIEF DESCRIPTION OF THE DRAWINGS

The related drawings in connection with the detailed description of the present invention to be made later are described briefly as follows, in which:

FIG. 1 is a schematic diagram of a nitride epitaxial layer structure according to a preferred embodiment of the present invention; and

FIG. 2 is a flow chart showing a process of forming the nitride epitaxial layer structure of FIG. 1.

### DETAILED DESCRIPTION OF THE PREFERRED EMBODIMENTS

In the following, a preferred embodiment of the present invention will be described in detail with reference to the attached drawings. The scales of certain portions of the structure are exaggeratedly enlarged for clarity, so as to facilitate the people skilled in the art to understand the details of the present invention more thoroughly.

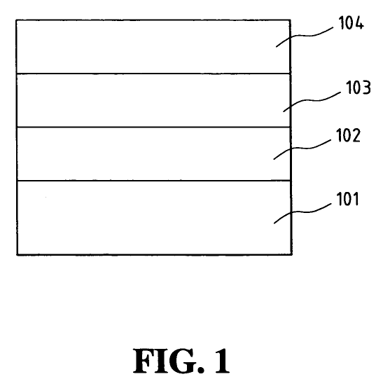

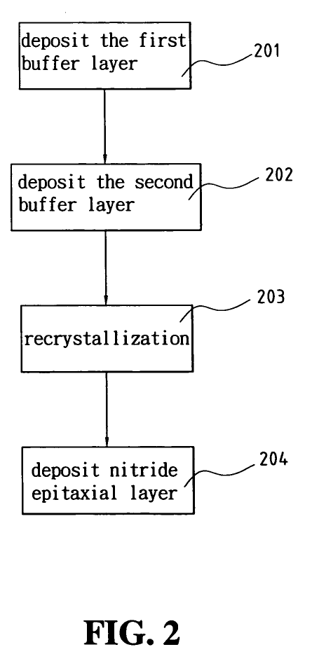

With reference to the drawings and in particular to FIG. 1, a nitride epitaxial layer structure according to the present invention; and FIG. 2 is formed by: stacking sequentially a first intermediate layer (102), a second intermediate layer(103), and a nitride epitaxial layer (104) on a substrate (101). And the purpose and function of the first intermediate layer (102) and the second intermediate layer (103) are to enhance the quality of the subsequently attached materials.

Next, referring to FIG. 2, the process for forming the nitride epitaxial layer structure in accordance with the present invention comprises the following steps:

Step 201, growing a first immediate layer (102) of high temperature aluminum-gallium-indium-nitride (Al_{1-x-y}GaₓIn_{y}N, x≧0, y≧0, 1≧x+y≧0) of appropriate thickness on the substrate (101) in the appropriate growth temperature through epitaxy. Wherein, due to the excessively large difference between lattice constant of the substrate (101) and that of first immediate layer (102), therefore, the first immediate layer (102) formed on the substrate (101) is of uneven surface.

Step 202, growing a second immediate layer (103) of low temperature aluminum-gallium-indium-nitride (Al_{1-x-y}GaₓIn_{y}N) of appropriate thickness on the first immediate layer (102) in the appropriate growth temperature through epitaxy, such that the second immediate layer thus created is loosely structured and in amorphous lattice alignment, so as to fill up the uneven surface portions of the first immediate layer (102).

Step 203, performing the re-crystallization of the second immediate layer (103) through the raised temperature, so as to make the lattices to form in orderly alignment.

Step 204, growing the high temperature nitride epitaxial layer (104) on the second intermediate layer (103) in the appropriate growth temperature through epitaxy.

In the above-mentioned process of growing the first immediate layer (102) of high temperature aluminum-gallium-indium-nitride (Al_{1-x-y}GaₓIn_{y}N) on the substrate (101), its growth temperature can be controlled to operate in the range of 900-1100° C., and its thickness is in the range of 5-20 Å. Due to the significant difference between the lattice constant of the substrate (101) and that of the first intermediate layer (102), which results in the uneven surface of the first immediate layer (102) grown on the substrate (101).

In the above-mentioned process of formation of the second immediate layer (103) of low temperature aluminum-gallium-indium-nitride (Al_{1-x-y}GaₓIn_{y}N) on the first intermediate layer (102), its growth temperature can be controlled to operate in the range of 200-900° C., and its thickness is in the range of 5-500 Å, such that the second immediate layer (103) thus created is loosely structured and in amorphous lattice alignment, and as such is sufficient to fill up the uneven surface portions of the first intermediate layer (102).

In the above-mentioned process of growing high temperature nitride epitaxial layer (104) on the second immediate layer (103), its growth temperature can be controlled to operate in the range of 800-1100° C.

The purpose of the preferred embodiment described above is only illustrative, and it is not intended to be construed as to be any restriction to the present invention. Therefore, any variations or modifications made within the spirit and scope of the present invention can be included in the scope of protection of the present invention.

What is claimed is:

1. A nitride epitaxial layer structure, comprising:
a substrate, made of sapphire (comprising C-Plane, R-Plane, and A-Plane), SiC(6H—SiC or 4H—SiC), Si, ZnO, GaAs, MgAl2O4, or single-crystal oxide with lattice constant close to N-compound semiconductor;
a first immediate layer, formed by stacking an appropriate thickness of high temperature aluminum-gallium-indium-nitride (Al_{1-x-y}GaₓIn_{y}N) on the substrate, wherein x≧0, y≧0, 1≧x+y≧0;
a second immediate layer, formed by stacking and then re-crystallizing an appropriate thickness of low temperature aluminum-gallium-indium-nitride (Al_{1-x-y}GaₓIn_{y}N) on the first immediate layer, wherein x≧0, y≧0, 1≧x+y≧0; and a nitride epitaxial layer, formed by stacking nitride epitaxial material on the second immediate layer.

2. The nitride epitaxial layer structure as claimed in claim 1, wherein the first immediate layer has a thickness of 5-20 Å.

3. The nitride epitaxial layer structure as claimed in claim 1, wherein the second immediate layer has a thickness of 5-500 Å.

4. A method of manufacturing nitride epitaxial layer, comprising the following steps:
(a) growing a first immediate layer of high temperature aluminum-gallium-indium-nitride (Al_{1-x-y}GaₓIn_{y}N) of appropriate thickness on a substrate in an appropriate high temperature through epitaxy, wherein x≧0, y≧0, 1≧x+y≧0;
(b) growing a second immediate layer of low temperature aluminum-gallium-indium-nitride (Al_{1-x-y}GaₓIn_{y}N) of appropriate thickness on the first immediate layer in an appropriate low temperature through epitaxy, wherein x≧0, y≧0, 1≧x+y≧0, such that the second immediate layer is loosely structured and in amorphous lattice alignment;
(c) performing re-crystallization of the second immediate layer in a raised temperature, such that its lattices are formed in orderly alignment; and
(d) growing a high temperature nitride epitaxial layer on the second immediate layer in an appropriate temperature through epitaxy.

5. The method of manufacturing nitride epitaxial layer as claimed in claim 4, wherein the first immediate layer is grown in a temperature of 900-1100° C.

6. The method of manufacturing nitride epitaxial layer as claimed in claim 4, wherein the first immediate layer has a thickness of 5-20 Å.

7. The method of manufacturing nitride epitaxial layer as claimed in claim 4, wherein the second immediate layer is grown in a temperature of 200-900° C.

8. The method of manufacturing nitride epitaxial layer as claimed in claim 4, wherein the second immediate layer has a thickness of 5-500 Å.

9. The method of manufacturing the nitride epitaxial layer as claimed in claim 4, wherein the nitride epitaxial layer is grown in a temperature of 500-1100° C.
